(19) United States
(12) Patent Application Publication
(10) Pub. No.: US 2003/0027362 A1
(43) Pub. Date: Feb. 6, 2003

(54) Method for determining deficient processes and deficient processing stations

(76) Inventors: Wen Fa Yang, Kung-Liao Hsiang (TW); Ming-Hua Liu, Taichung (TW); Eric C.H. Kuo, Chia-Yi Hsien (TW); Jasmine Wu, Changhua (TW)

Correspondence Address: CHARLES C.H. WU & ASSOCIATES, Suite 710, 7700 IRVINE CENTER DRIVE, Irvine, CA, 92618-3043, US

(21) Appl. No.: 09/922,437

(22) Filed: Aug. 3, 2001

(51) Int. Cl. H01L 21/66

(52) U.S. Cl. 438/14

(57) ABSTRACT

A method determines the deficient processes and deficient processing stations in the manufacture of a product fabricated by lots through a plurality of processes performed by a plurality of processing stations. From a plurality of lots, the good lots are distinguished from the bad lots. By using the process history of each good and bad lot, a good lot ratio and a bad lot ratio that are respectively produced by each process performed by one of the processing stations are calculated. The processes/processing stations are arranged according to a decreasing order of their bad lot ratios. The most probable deficient processes/processing stations are those which are arranged at the top of the arranged order.

### BACKGROUND OF THE INVENTION

1. Field of the Invention

The invention relates to a quality control method. More particularly, the present invention relates to a quality control method that is implemented in semiconductor processes to determine the deficient processes and deficient processing stations.

2. Description of the Related Art

In semiconductor wafer processes, twenty-five units of wafers are conventionally held within a case to carry out a series of fabrication steps, and these 25 units of wafers are referred to as a lot. After completing all the semiconductor processes, the lots of wafers are conventionally tested. The results of the tests primarily are used to discard the bad wafers and to control the manufacturing process to ensure the quality of the lots of wafers produced. However, once a deficiency is detected during the tests, the hardest task is to determine the cause of the deficiency among the hundreds of processes performed by numerous processing stations to achieve the wafers.

To find the cause of the deficiency, one approach is to list out all the processes and processing stations through which the lots of wafers have been manufactured, and evaluate the cause of the deficiency by performing an inference from the effects to the causes. Such a practice can be time-consuming and entirely relies on the accumulated knowledge and experience of the skilled artisan. Thus, a more systematic method is desired that can integrate all the information of the manufacturing process and can systematically be applied to find the deficient processes and processing stations each time bad lots are detected.

### SUMMARY OF THE INVENTION

A major aspect of the present invention is thus to provide a systematic method for determining the deficient processes and processing means in the manufacture of a product such as semiconductor wafers. By integrating and processing the information about the processes and processing means of the manufacture of the product, the present invention can systematically and rapidly determine the deficient processes and processing means.

To accomplish at least the foregoing objectives, the method of the present invention, which is applied to the manufacture of a product fabricated by lots through a plurality of processes performed by a plurality of processing stations, comprises the following steps. From a plurality of lots of a product that are fabricated, the good lots are distinguished from the bad lots. Then, the process history of each good and bad lot is generated. The process history includes the information about all the processes and processing stations from which each lot is fabricated. Then, a good lot ratio and a bad lot ratio is calculated for each process performed by one processing station, wherein the good (or respectively bad) lot ratio of a process/processing station is the percentage of good (or respectively bad) lots that have gone through the process performed by the processing station relative to the total number of lots fabricated. Then, the processes/processing stations are arranged in according to a decreasing order of their bad lot ratios. From the arranged order of the processes/processing stations, the deficient processes/processing stations are easily determined by their positions at the top of the arranged order

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow diagram schematically illustrating a method for determining the deficient processes and processing stations in the manufacture of a product, according to preferred embodiment of the present invention;

FIG. 2 is an analysis chart of good and bad lots according to an embodiment of the present invention; and

FIG. 3 is another analysis chart corresponding to an orderly arrangement of the analysis chart of FIG. 2 according to a preferred embodiment of the present invention.

### DESCRIPTION OF THE PREFERRED EMBODIMENTS

The following detailed description of the embodiments and examples of the present invention with reference to the accompanying drawings is only illustrative and not limiting.

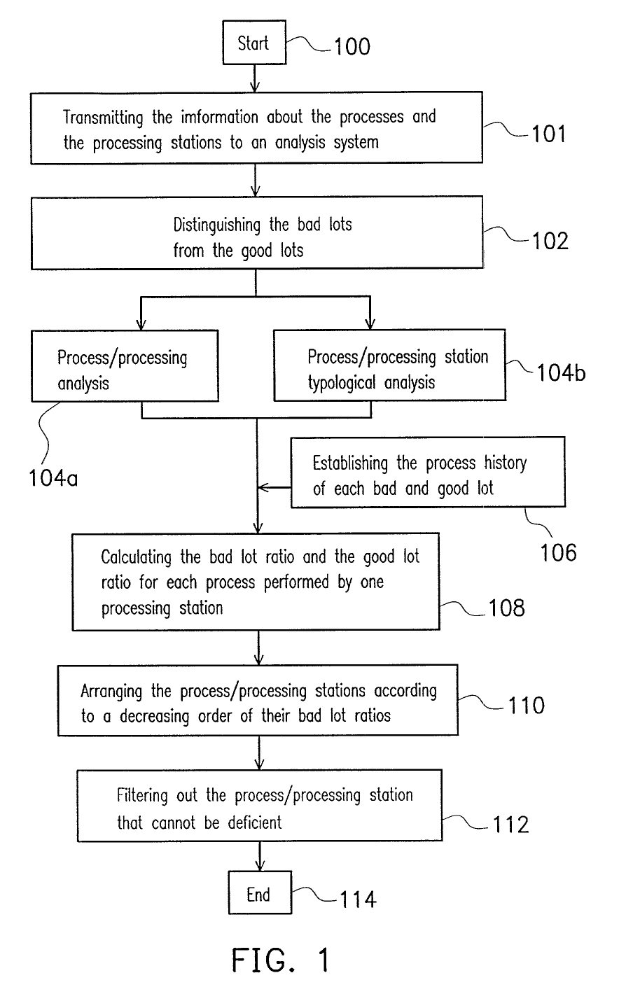

Referring now to FIG. 1, a flow diagram schematically illustrates a method for determining the deficient processes and the deficient processing stations in the manufacture of a product according to a preferred embodiment of the present invention. A product is usually manufactured by lots that pass through a plurality of processes performed by various processing stations. The method of the present invention is described hereafter via the example of the manufacture of semiconductor wafers for electronic component devices. However, it is apparent that the present invention also can be applied to the manufacture of other products produced by lots. When starting at step 100, information about the whole process history of the manufacture of a product taken within a given period of time, comprising all the processes performed by the processing stations, is transmitted via a computer network to an analysis system (step 101). The analysis system distinguishes the bad lots and the good lots among the manufactured lots of wafers. The distinction of a good lot from a bad lot can be evaluated by, for example, determining whether each lot satisfies a good product ratio. If the number of good products within the lot is less than the required good product ratio, the lot is bad, while if the number of good products of the lot is higher than the required good product ratio, the lot is evaluated as good.

Then, various types of analysis can be performed. In the present description, the notation “process/processing station” indicates a process and a processing station that performs the process. In the present invention, a first type of analysis is a process/processing station analysis (step 104a), which consists of analyzing each of the processes respectively performed by one processing station to produce the good and/or bad lots. Another type of analysis is a process/processing station typological analysis (step 104b), which consists of analyzing each of the processes performed by the processing stations that are arranged in a plurality of groups of processing stations. The typological analysis can include, for example, analyzing the bad and good lots produced by a deposition process performed by a group of deposition processing stations constructed by the same manufacturer.

Then, the process history of each bad lot and each good lot is established (step 106). The process history comprises, for example, the information that indicates the processes that have been performed and the processing stations that have been used, and the information that indicates the number of times the bad and good lots have passed through each process performed by one processing station. For each process performed by a processing station, a good lot ratio and a bad lot ratio are calculated (step 108). The bad lot ratio of each process/processing station is calculated by:

Bad lot ratio (%)=[number of bad lots that have passed through the process/processing station÷total number of bad lots]×100.

Similarly, the good lot ratio of each process/processing station is calculated by:

Good lot ratio (%)=[number of good lots that have passed through the process/processing station÷total number of good lots]×100.

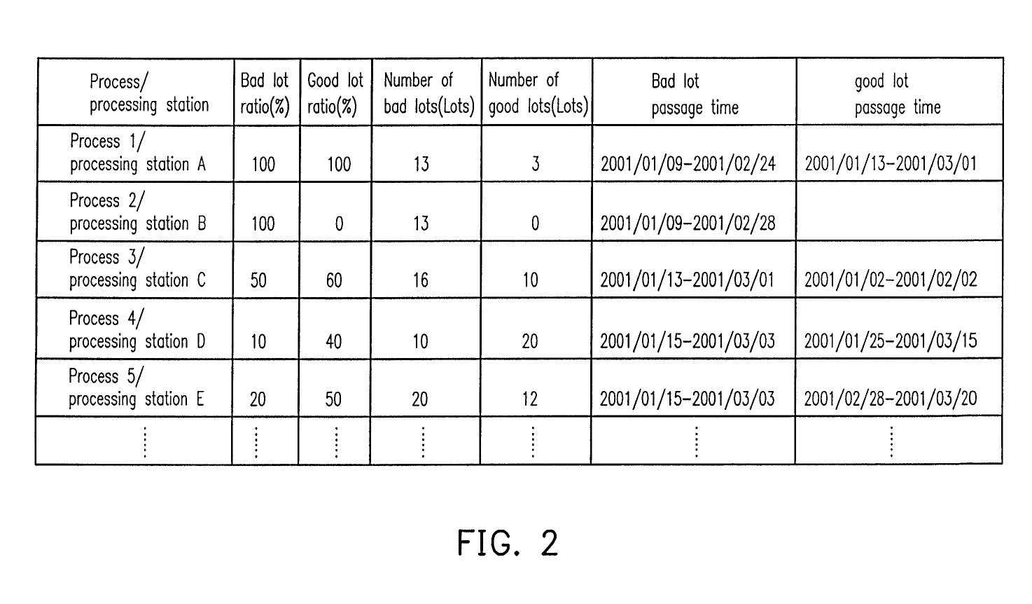

Referring to FIG. 2, an analysis chart shows the results obtained after step 108 is performed. A first column shows all the processes/processing stations through which each bad and good lot of the product has passed. The bad lot ratio, the good lot ratio, the number of bad lots, and the number of good lots of each process/processing station are respectively arranged in the other four columns. The time during which the bad and good lots have passed through each process/processing station are respectively shown in the last two columns.

A first preliminary cross-analysis for determining the deficient processes/processing stations can be performed by evaluating both the bad and good lot ratios of each process/processing station as described hereafter. If the bad lot ratio of a given process performed by a given processing station is high while the good lot ratio is low, the process performed by the processing station very likely is deficient. If the bad lot ratio is high while the good ratio is also high, the process performed by the processing station less likely is deficient. If the bad lot ratio is low while the good lot ratio is also low, the probability that the process performed by the processing station is deficient is lower than the probability of the case in which both the bad lot ratio and the good ratio are high. Finally, if the bad lot ratio is low while the good lot ratio is high, the probability that the process performed by the processing station is deficient is the lowest. Different levels of deficiency thus are established to evaluate the different processes performed by different processing stations. When a deficiency is clearly detected, which is the case when the bad lot ratio is high while the good lot ratio is low, the record of the time during which each process has been performed indicates when the deficiency occurred. The present invention also provides another analysis method for determining the deficient processes as described hereafter.

After the bad and good lot ratios are evaluated for each process/processing station (step 108), the processes/processing stations are arranged by the analysis system according to a decreasing order of their respective bad lot ratios (step 110). The processes/processing stations having the same bad lot ratios are arranged according to an increasing order of their respective good lot ratios.

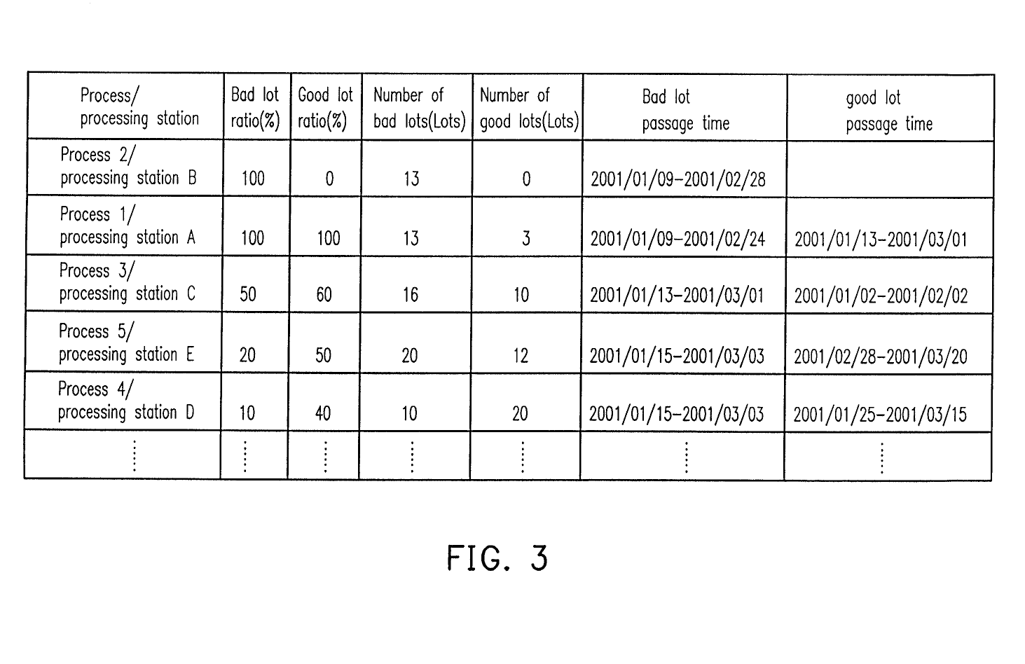

Referring to FIG. 3, an analysis chart schematically illustrates the results after the above arrangement is applied to the processes/processing stations of FIG. 2 according to a preferred embodiment of the present invention. The processes/processing stations that are located at the top of the arranged order are evaluated as those which are most likely deficient. In the example of FIG. 3, process 2 performed by the processing station B has the greatest probability of deficiency, the deficiency occurring at a time between the date Jan. 9, 2001 and the date Feb. 2, 2001.

Referring to FIG. 1, after the orderly arrangement has been achieved, the processes that actually cannot be deficient are filtered out from the analysis chart (step 112). The remaining processes are arranged according to a decreasing order of their probability of deficiency. The analyst thus is advantageously aided in the search for the deficient processes and processing stations. The method is ended at step 114.

The present invention provides at least the following advantages. In comparison with the conventional manual search for the deficient processes, the method of the present invention is less time-consuming, more efficient and more reliable. Moreover, by establishing a process history for each product, the method of the present invention advantageously allows for the integration of the manufacturing processes with the processing means.

It will be apparent to those skilled in the art that various modifications and variations can be made to the structure of the present invention without departing from the scope or spirit of the invention.

What is claimed is:

1. A method for determining deficient processes and processing stations used in a manufacturing process of a product fabricated by lots, the manufacturing process including a plurality of processes performed by a plurality of processing stations, the method comprising:
distinguishing good lots from bad lots among a plurality of lots of the product;
establishing a process history for each of the bad lots and for each of the good lots, the process history comprising a plurality of information that indicate the processes and the processing stations through which each good and bad lot has passed;
calculating a good lot ratio and a bad lot ratio for each of the processes performed by one of the processing stations taken from the process histories, wherein the good lot ratio is the percentage of good lots produced by the process performed by the processing station relative to the total number of lots produced, while the bad lot ratio is the percentage of bad lots produced by the process performed by the processing station relative to the total number of lots produced, the total number of lots being the sum of all the good and bad lots;
arranging the processes according to a decreasing order of their respective bad lot ratio; and
evaluating the probability of deficiency of each of the processes performed by one of the processing stations using the arranged order of the processes, wherein the probability of deficiency of the processes arranged at the top of the arranged order is greater.

2. The method of claim 1, wherein the step of distinguishing the good lots from the bad lots is carried out by determining whether each of the lots satisfies a good product ratio.

3. The method of claim 1, wherein the processes with equal bad lot ratios are arranged by increasing order of their respective good lot ratio.

4. The method of claim 1, wherein the process history of each bad lot and each good lot comprises information that indicates the number of times each of the processes have been performed.

5. The method of claim 1, wherein the process history of each bad lot and each good lot comprises information that indicates the time during which each of the processes are performed.

6. A method for determining the deficient processes and processing stations used in a manufacturing process of a product fabricated by lots, the manufacturing process having a plurality of processes performed by a plurality of processing stations, the method comprising:
distinguishing good lots from bad lots among a plurality of lots of the product;
establishing a process history for each of the bad lots and for each of the good lots, the process history comprising a plurality of information about the processes and the processing stations gathered from a plurality of groups of processing stations;
calculating a good lot ratio and a bad lot ratio for each of the processes performed by one of the groups of processing stations taken from the process histories, wherein the good lot ratio is calculated by the percentage of good lots produced by the process performed by the group of processing stations relative to the total number of lots produced, while the bad lot ratio is calculated by the percentage of bad lots produced by the process performed by the group of processing stations relative to the total number of lots produced, the total number of lots being the sum of all the bad and good lots;
arranging the processes according to a decreasing order of their respective bad lot ratios; and
evaluating the probability of deficiency of each of the processes performed by one of the group of processing stations using the arranged order of the processes, wherein the probability of deficiency of the processes arranged at the top of the order is greater.

7. The method of claim 6, wherein the processing stations of a same group of processing stations perform a same process.

8. The method of claim 6, wherein the processing stations of a same group of processing stations are fabricated by a same manufacturer.

9. The method of claim 6, wherein the step of distinguishing the good lots from the bad lots is carried out by determining whether each of the lots satisfies a good product ratio.

10. The method of claim 6, wherein the processes with equal bad lot ratios are arranged by increasing order of their respective good lot ratio.

11. The method of claim 6, wherein the process history of each bad lot and each good lot comprises information about the number of times each of the processes have been performed.

12. The method of claim 6, wherein the process history of each bad lot and each good lot comprises information that indicates the time during which each of the processes are performed.
